(19) United States
(12) Patent Application Publication
(10) Pub. No.: US 2026/0040897 A1
(43) Pub. Date: Feb. 5, 2026

(54) METHOD FOR PREDICTING MISALIGNMENT DATA OF A WAFER USING AN IMPROVED NEURAL NETWORK LEARNING METHOD

(71) Applicant: Samsung Electronics Co., Ltd., Suwon-si (KR)

(72) Inventors: DeogHo Choi, Suwon-si (KR); Sung Chai Kim, Suwon-si (KR); Euiseok Kum, Suwon-si (KR); Sung-Won Park, Suwon-si (KR)

(21) Appl. No.: 19/173,997

(22) Filed: Apr. 9, 2025

(30) Foreign Application Priority Data
Aug. 2, 2024 (KR) 10-2024-0103442

(51) Int. Cl. H01L 21/66; G06N 3/048; G06N 3/082; H01L 21/68

(52) U.S. Cl. CPC H01L 22/26; G06N 3/048; G06N 3/082; H01L 21/681

(57) ABSTRACT

A method for obtaining misalignment data of an exposure equipment, performed by a computing device comprising at least one processor, includes obtaining a first latent vector from alignment data of a plurality of shots within a wafer measured based on a plurality of light sources having different wavelengths, using a first graph neural network (GNN), obtaining a third latent vector by reflecting an importance of the plurality of light sources and the plurality of shots in the first latent vector, obtaining misalignment data for each of the plurality of shots from the third latent vector using a first multilayer perceptron (MLP) neural network, and adjusting an equipment control value of the exposure equipment based on the misalignment data for each of the plurality of shots in the wafer.

### CROSS-REFERENCE TO RELATED APPLICATION(S)

This U.S. non-provisional application claims priority under 35 USC § 119 to Korean Patent Application No. 10-2024-0103442, filed on Aug. 2, 2024, in the Korean Intellectual Property Office, the disclosure of which is herein incorporated by reference in its entirety.

### BACKGROUND

Example embodiments relate to a method for obtaining misalignment data of shots within a wafer and using a neural network learning method for predicting misalignment data of the alignment key of the wafer.

An integrated circuit manufactured through semiconductor processes includes a plurality of layers having different patterns, and each of the layers may be formed through an exposure process. Successively exposed layers may need to be aligned to ensure appropriate operations of the manufactured integrated circuit.

### SUMMARY

Example embodiments provide a method for obtaining misalignment data based on alignment data.

According to example embodiments, a method for obtaining misalignment data of an exposure equipment for a wafer, performed by a computing device comprising at least one processor, includes obtaining a first latent vector from alignment data of a plurality of shots within a wafer measured based on a plurality of light sources having different wavelengths, using a first graph neural network (GNN), obtaining a third latent vector by reflecting an importance of the plurality of light sources and the plurality of shots in the first latent vector, obtaining misalignment data for each of the plurality of shots from the third latent vector using a first multilayer perceptron (MLP) neural network, and adjusting an equipment control value of the exposure equipment based on the misalignment data for each of the plurality of shots in the wafer.

The alignment data may correspond to a single target layer among a plurality of layers stacked on the wafer, and may be data measured for each of the plurality of light sources based on alignment keys, respectively corresponding to the plurality of shots, before an exposure operation on the target layer, and the misalignment data may include information on how much each of the plurality of shots is misaligned relative to a layer exposed prior to the target layer.

The obtaining the latent vector may include converting the alignment data into graphical input data and inputting the input data to the first GNN to obtain the first latent vector.

The obtaining the third latent vector by reflecting the importance may include obtaining a second latent vector by reflecting an importance of each of the plurality of light sources in the first latent vector and obtaining the third latent vector by reflecting an importance of each of the plurality of shots in the second latent vector.

The obtaining the second latent vector may include calculating a channel-wise attention score corresponding to each of the multiple light sources from the first latent vector using a channel attention module and obtaining the second latent vector based on a multiplication of the channel-wise attention score and the first latent vector.

The channel attention module may include a second MLP neural network, and the calculating the channel-wise attention score may include obtaining a first vector comprising a channel-wise maximum value through a maximum pooling operation on the first latent vector and obtaining a second vector comprising a channel-wise average value through an average pooling operation on the first latent vector, inputting the first vector and the second vector to the second MLP neural network to obtain a third vector corresponding to the first vector and a fourth vector corresponding to the second vector, and obtaining the channel-wise attention scores from a sum of the third vector and the fourth vector using a sigmoid activation function.

The obtaining the third latent vector may include calculating a shot-wise attention score corresponding to each of the plurality of shots from the second latent vector using a spatial attention module and obtaining the third latent vector based on a multiplication of the shot-wise attention score and the second latent vector.

The spatial attention module may include a second GNN, and the calculating the shot-wise attention score may include obtaining a fifth vector comprising a shot-wise maximum value through a maximum pooling operation on the second latent vector and obtaining a sixth vector comprising a shot-wise average value through an average pooling operation on the second latent vector, inputting the concatenated fifth and sixth vectors to the second GNN, and obtaining the shot-wise attention score from an output of the second GNN using a sigmoid activation function.

The misalignment data may include x-axis misalignment data including a misalignment component in an x-axis direction and y-axis misalignment data including a misalignment component in a y-axis direction, and the first MLP neural network may include an x-axis MLP neural network and a y-axis MLP neural network.

The obtaining the misalignment data may include flattening the third latent vector, inputting the flattened third latent vector to the x-axis MLP neural network to obtain the x-axis misalignment data, and inputting the flattened third latent vector to the y-axis MLP neural network to obtain the y-axis misalignment data.

The method may include updating weights included in the first GNN and the first MLP neural network using a first loss function to reduce an error between the misalignment data and misalignment label data corresponding to the alignment data.

The first loss function is defined by a mean squared error (MSE) below,

$$MSE = \frac{1}{N} {\sum }_{i = 1}^{N} {( {y}_{i} - {y}_{i}^{′} )}^{2}$$

where N is a size of a batch, yᵢ is misalignment data corresponding to an i-th wafer among N wafers in the batch, and y′ᵢ is misalignment label data corresponding to the i-th wafer among the N wafers in the batch.

The method may include updating weights included in the first GNN using a second loss function for contrastive learning to reflect a similarity between misalignment shape indices of wafers in a batch in the third latent vector. A misalignment shape index of each of the wafers may be coefficients obtained through polynomial regression from misalignment label data corresponding to each of the wafers. Using polynomial regression may reduce computational requirements.

The second loss function may be defined by correlation loss below,

$$correlation loss = \frac{1}{{n}^{2}} {\sum }_{i = 0}^{n} {\sum }_{j = 0}^{n} {α}_{i j} {β}_{i j} \vert {ϕ}_{i j} - {Ω}_{i j} \vert$$

where n is a size of a batch, αᵢⱼ is an n×n square matrix having a value of 0 when i and j are the same and having a value of 1 when i and j are different from each other, βᵢⱼ is an indicator matrix prepared to apply different values depending on characteristics of a target layer, ϕᵢⱼ is a cosine similarity matrix of the third latent vectors corresponding to arbitrary two wafers in the batch, and Ωᵢⱼ is a cosine similarity matrix of misalignment shape indices corresponding to the arbitrary two wafers in the batch.

According to example embodiments, a method for obtaining misalignment data of an exposure equipment for a wafer using a neural network model includes converting alignment data of a plurality of shots measured for each of a plurality of light sources into input data comprising a positional relationship between the plurality of shots, inputting the input data to a graph neural network (GNN) to obtain a first latent vector, obtaining a third latent vector by reflecting an importance of each light source and an importance of each shot in the first latent vector, predicting misalignment data for each of the plurality of shots from the third latent vector using a multilayer perceptron (MLP) neural network, and adjusting an equipment control value of the exposure equipment based on the misalignment data for each of the plurality of shots in the wafer.

The obtaining the third latent vector may include calculating a channel-wise attention score corresponding to each of the plurality of light sources from the first latent vector using a channel attention module and obtaining a second latent vector based on a multiplication the product operation of the channel-wise attention scores and the first latent vector, and calculating a shot-wise attention score corresponding to each of the plurality of shots from the second latent vector using a spatial attention module and obtaining the third latent vector based on a multiplication of the shot-wise attention score and the second latent vector.

The method may include updating weights included in the GNN, the channel attention module, the spatial attention module, and the MLP neural network using a first loss function to reduce an error between the misalignment data and misalignment label data corresponding to the alignment data.

The method may include updating weights included in the GNN, the channel attention module, and the spatial attention module using a second loss function for contrastive learning to reflect a relationship between the misalignment shape indices of wafers in a batch in the third latent vector. A misalignment shape index of each of the wafers may be coefficients obtained through polynomial regression from the misalignment label data corresponding to each of the wafers.

The second loss function may be defined by correlation loss below,

$$correlation loss = \frac{1}{{n}^{2}} {\sum }_{i = 0}^{n} {\sum }_{j = 0}^{n} {α}_{i j} {β}_{i j} \vert {ϕ}_{i j} - {Ω}_{i j} \vert$$

where n is a size of a batch, αᵢⱼ is an n×n square matrix having a value of 0 when i and j are the same and having a value of 1 when i and j are different from each other, βᵢⱼ is an indicator matrix prepared to apply different values depending on characteristics of a target layer, ϕᵢⱼ is a cosine similarity matrix of the third latent vectors corresponding to arbitrary two wafers in the batch, and Ωᵢⱼ is a cosine similarity matrix of misalignment shape indices corresponding to the arbitrary two wafers in the batch.

According to example embodiments, a method for obtaining misalignment data of an exposure equipment for a wafer includes converting alignment data of a plurality of shots within a wafer, measured using a plurality of light sources having different wavelengths, into a graphical input data, inputting the graphical input data to a graph neural network (GNN) to obtain a first latent vector, obtaining a third latent vector by reflecting an importance of the plurality of light sources and the plurality of shots in the first latent vector, flattening the third latent vector, inputting the flattened third latent vector to an x-axis MLP neural network to predict x-axis misalignment data comprising an x-axis misalignment component, inputting the flattened third latent vector to a y-axis MLP neural network to predict y-axis misalignment data comprising a y-axis misalignment component, and adjusting an equipment control value of the exposure equipment based on the misalignment data for each of the plurality of shots in the wafer.

### BRIEF DESCRIPTION OF DRAWINGS

FIG. 1 is a block diagram of a computing device according to example embodiments.

FIG. 2 is a diagram illustrating an example of a structure of a preprocessing module and a neural network model according to example embodiments.

FIG. 3 is a diagram illustrating an example of a physical phenomenon caused by damage to an alignment key.

FIG. 4 is a diagram illustrating an example of alignment data according to example embodiments.

FIG. 5 is a diagram illustrating an example of input data according to example embodiments.

FIG. 6 is a diagram illustrating an example of misalignment data obtained according to example embodiments.

FIG. 7 is a diagram illustrating an example of a misalignment shape index.

FIG. 8 is a diagram illustrating an example of a misalignment shape index.

FIG. 9 is a diagram illustrating an example of a configuration of a channel attention module of FIG. 2.

FIG. 10 is a diagram illustrating an example of a configuration of a spatial attention module of FIG. 2.

FIG. 11 is a flowchart illustrating a method for obtaining misalignment data according to example embodiments.

### DETAILED DESCRIPTION

Hereinafter, example embodiments will be described with reference to the accompanying drawings.

The term “first,” “second,” or the like used herein may modify various elements regardless of the order and/or priority thereof, and is used only for distinguishing one element from another element, without limiting example embodiments. Therefore, the ordering of the terms “first”, “second” etc. does not necessarily imply an ordering as these terms may be used interchangeably. Additionally, the existence of a “third” element does not imply that both the “second” and “first” elements exist. It may be possible to have a “first” element and a “third” element without having a “second” element, in some embodiments.

An integrated circuit with multiple layers may have different patterns and may be formed through an exposure process. Alignment of successively exposed layers may be needed for proper operation of the manufactured integrated circuit. An alignment key corresponding to each shot within a wafer may be provided on a scribe lane of a wafer, and an exposure position for each shot may be determined by measuring a position of the alignment key.

Processes such as etching or chemical mechanical polishing (CMP) may cause deformation of such an alignment key. The deformation of an alignment key may cause a deviation between a measured position and an actual position of the alignment key, resulting in pattern misalignment between layers of an integrated circuit.

The level of misalignment in manufacturing processes may be managed by periodically measuring the level of misalignment and adjusting control values of exposure equipment based on the measured level. In general, the level of misalignment is measured in an after cleaning inspection (ACI) following exposure. Accordingly, levels of misalignment are measured only for a small number of sampled wafers, and equipment control values are adjusted manually.

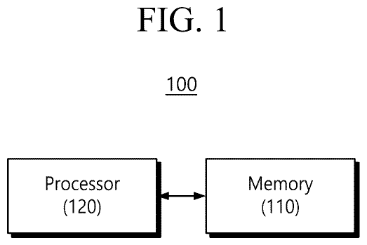

FIG. 1 is a block diagram of a computing device according to example embodiments. Referring to FIG. 1, the computing device 100 may include a memory 110 and a processor 120.

The memory 110 may store various programs and data to control the operation of the computing device 100. To this end, the memory 110 may include at least one of a random access memory (RAM), a read-only memory (ROM), a flash memory, a hard disk, a solid state drive (SSD), a card-type memory (for example, an SD or XD memory), a magnetic memory, a magnetic disk, or an optical disk. The computing device 100 may operate in relation to a web storage element performing storage functions of the memory 110 on the internet.

The memory 110 may store alignment data. The alignment data may be data on positions of a plurality of shots in a wafer measured based on a plurality of light sources having different wavelengths. For example, the alignment data may correspond to a single layer, among a plurality of layers stacked on the wafer. In addition, the alignment data may be data measured for each of the plurality of light sources based on alignment keys corresponding to the plurality of shots before an exposure operation is performed on a target layer. Exposure positions of the plurality of shots of the target layer may be determined based on the measured alignment data.

According to example embodiments, the alignment data stored in the memory 110 may be training data for training a neural network model. In some embodiments, the alignment data stored in the memory 110 may be prediction data for predicting misalignment data. When the alignment data is training data, the memory 110 may store misalignment label data corresponding to the alignment data. The misalignment label data may be actual misalignment data measured through an electron microscope, or the like, after an exposure process is performed based on the alignment data. The misalignment data may include information on how much each of the plurality of shots is misaligned relative to a previously exposed layer. The neural network model may be configured to perform dimensionality reduction, thereby reducing the size of the data set such that the model may execute with decreased memory and/or computational requirements.

The memory 110 may store a neural network model for predicting misalignment data based on the alignment data. According to example embodiments, the neural network model stored in the memory 110 may include a graph neural network (GNN) model and a multilayer perceptron (MLP) neural network model. The neural network model may include an attention module for applying an attention to an intermediate feature map of the GNN model. According to example embodiments, the attention module may include a channel attention module for applying importance of each light source and a spatial attention module for applying importance of each shot.

The memory 110 may store a preprocessing module for preprocessing data to be input to the neural network model.

The processor 120 may control the overall operation of the computing device 100. The processor 120 may include one or more cores. The processor 120 may include at least one of a central processing unit (CPU), a graphics processing unit (GPU), an application processor (AP), a communication processor (CP), or a tensor processing unit (TPU), and may execute program codes stored in the memory 110 to perform the operation of the computing device 100 according to various embodiments.

For example, the processor 120 may obtain misalignment data from alignment data using module(s) and neural network model stored in the memory 110.

For example, the processor 120 may extract a first latent vector from the alignment data using the GNN model. To do this, the processor 120 may convert the alignment data into a graphical input data using a preprocessing module. The input data may include a vertex V and an edge E. The vertex V may have an alignment data value associated with each light source for each of the plurality of shots. The edge may include information on a positional relationship between the plurality of shots. The processor 120 may input the input data to the GNN to obtain the first latent vector.

The processor 120 may obtain a second latent vector by reflecting the importance of the plurality of light sources and the plurality of shots in the first latent vector. For example, the processor 120 may obtain a third latent vector by reflecting the importance of each of the plurality of light sources in the first latent vector, and obtain a second latent vector by reflecting the importance of each of the plurality of shots in the third latent vector. However, example embodiments are not limited thereto. According to some embodiments, the processor 120 may obtain a third latent vector by reflecting the importance of each shot in the first latent vector, and then obtain a second latent vector by reflecting the importance of each light source in the obtained third latent vector. When reflecting the importance of each light source and each shot, the processor 120 may use an attention module.

Accordingly, the processor 120 may obtain misalignment data for each of the plurality of shots from the second latent vector using the MLP neural network model. According to example embodiments, the misalignment data may include x-axis misalignment data, including a misalignment component in an x-axis direction, and y-axis misalignment data including a misalignment component in a y-axis direction. To this end, the MLP neural network may include an x-axis MLP neural network and a y-axis MLP neural network. According to example embodiments, the processor 120 may obtain x-axis misalignment data from the second latent vector using the x-axis MLP neural network and obtain y-axis misalignment data from the second latent vector using the y-axis MLP neural network.

The processor 120 may learn the neural network model to predict misalignment data more accurately from the alignment data. For example, the processor 120 may update weights, included in the GNN and MLP neural networks, using a first loss function. The first loss function may be a function defined by a mean squared error, but example embodiments are not limited thereto.

For example, the processor 120 may input the training misalignment data to the neural network model to obtain misalignment data as described above. Also, the processor 120 may calculate the first loss function based on the misalignment data obtained through the neural network model and the misalignment label data corresponding to the training alignment data. Accordingly, the processor 120 may update the weights, included in the GNN, the attention module, and the MLP neural network, through a backpropagation algorithm to reduce an error calculated through the first loss function.

The processor 120 may update the weights, included in the GNN, using a second loss function for contrastive learning to reflect similarity between the misalignment shape indices of wafers in the second latent vector. The misalignment shape index may be an index indicating a shape in which a plurality of shots are misaligned within the wafer.

According to example embodiments, the processor 120 may obtain a misalignment shape index of the wafer from the misalignment label data through polynomial regression. The misalignment shape index may be coefficients of a polynomial used for polynomial regression. The misalignment shape index obtained through the polynomial regression may be a continuous value, so that it may be difficult to discretely categorize the misalignment shape index. Therefore, according to example embodiments, the second loss function may be defined based on cosine similarity.

For example, the processor 120 may calculate the second loss function based on cosine similarity between misalignment shape indices of wafers in a batch and cosine similarity between second latent vectors of the wafers in the batch. Accordingly, the processor 120 may update the weights included in the GNN and attention module through a backpropagation algorithm to reduce an error calculated by the second loss function.

According to above-described various embodiments, misalignment data may be obtained using alignment data. Since the misalignment data is obtained through a neural network model based on the alignment data, the misalignment data may be obtained before an exposure operation on a corresponding layer. In addition, since the alignment data is whole number data measured before exposing all or a subset of wafers, misalignment data for all or a subset of wafers may be obtained.

The misalignment data obtained as described above may be used to automatically detect a time point at which a control value of exposure equipment is updated. For example, the misalignment data may be predicted in real time for wafers in a manufacturing process using the neural network model, as described above. Also, the misalignment shape indices for the wafers may be predicted in real time based on the predicted misalignment data. A variation trend of the misalignment shape indices of the wafers may be predicted based on the predicted misalignment shape indices. A time point, at which the misalignment shape index begins to vary rapidly, may be estimated as a time point at which the control value of the exposure equipment needs to be updated due to reasons such as the alignment key being deformed beyond an allowable range.

Accordingly, the misalignment data for wafers may be predicted in real time in the manufacturing process and the variation trend of the misalignment shape indices may be predicted based on the predicted misalignment data, thereby automatically detecting the time point at which the control value of the exposure equipment is updated. The detected update time point may be provided to equipment engineers through an appropriate notification. In this regard, the processor 120 may clearly reflect the similarity or difference between the misalignment shape indices of the wafers in the second latent vector through contrastive learning, as described above. As a result, the variation trend of the misalignment shape indices may be detected more accurately.

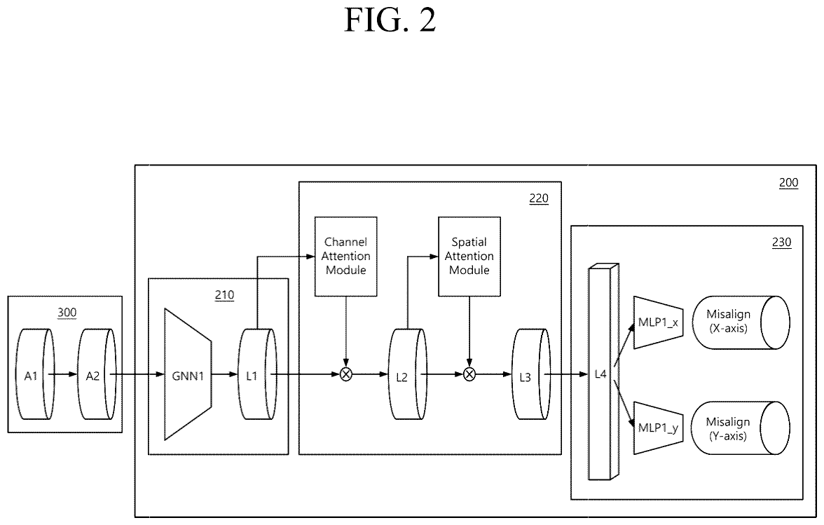

Hereinafter, the configuration and operation of the neural network model according to example embodiments will be described in detail with reference to FIGS. 2 to 8.

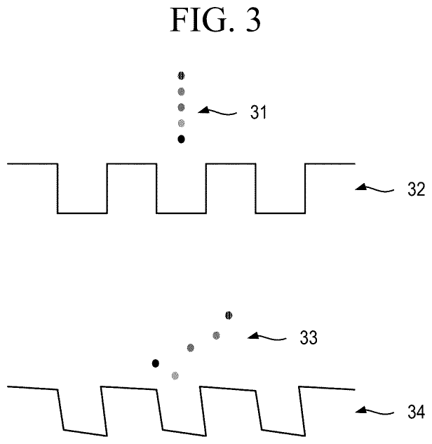

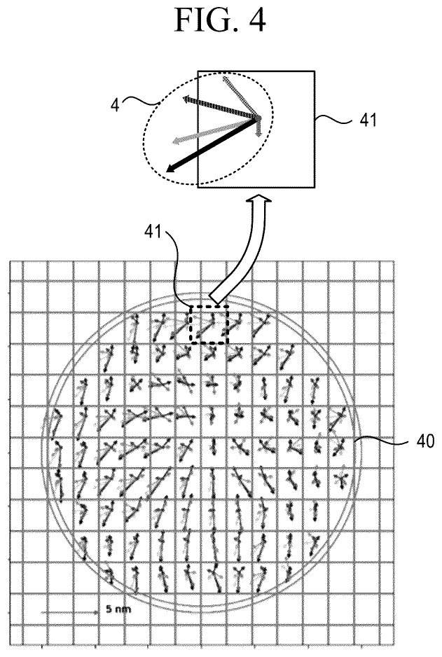

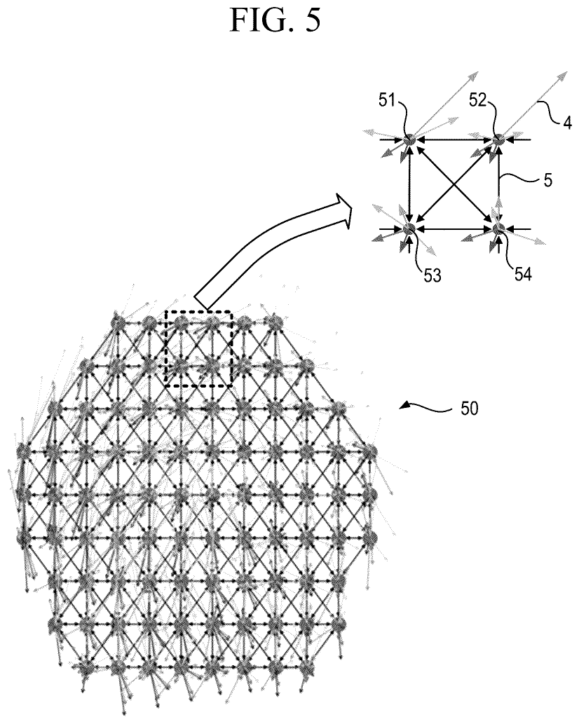

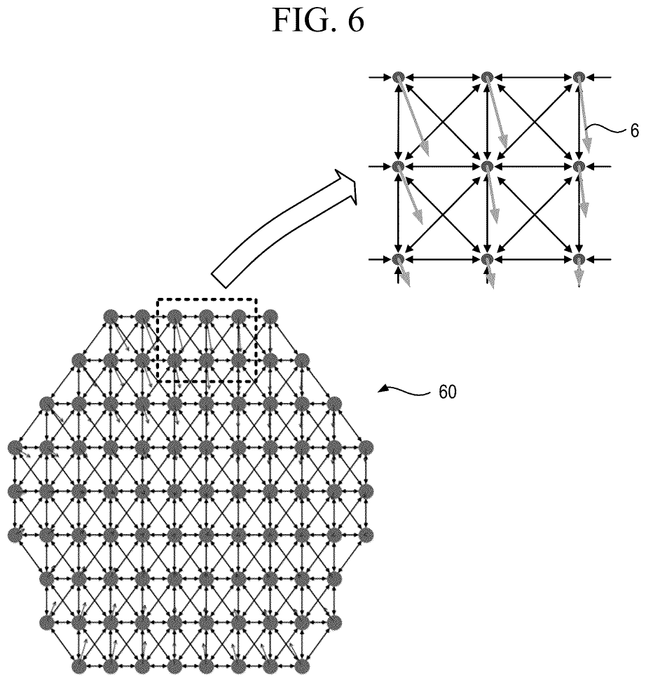

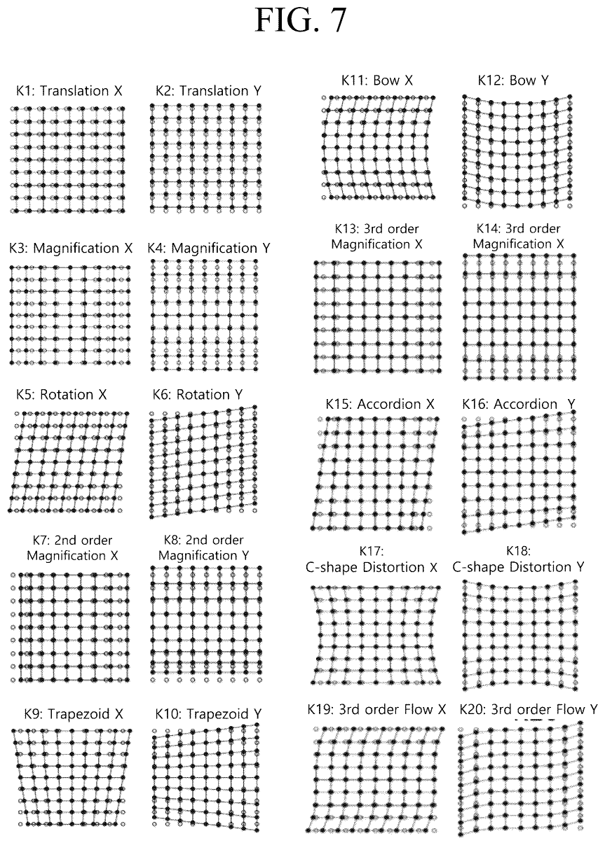

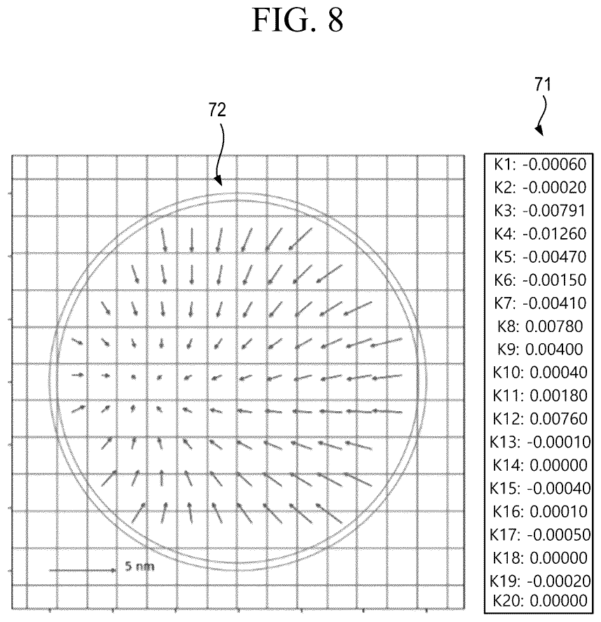

FIG. 2 is a diagram illustrating an example of a structure of a preprocessing module and a neural network model according to example embodiments. FIG. 3 is a diagram illustrating an example of a physical phenomenon caused by damage to an alignment key. FIG. 4 is a diagram illustrating an example of alignment data according to example embodiments. FIG. 5 is a diagram illustrating an example of input data according to example embodiments. FIG. 6 is a diagram illustrating an example of misalignment data obtained according to example embodiments. FIGS. 7 and 8 are diagrams, each illustrating an example of a misalignment shape index.

Referring to FIG. 2, a preprocessing module 300 may convert alignment data A1 into graphical input data A2. In example embodiments, the alignment data A1 may include information related to positions of alignment keys of a plurality of shots in a wafer measured based on a plurality of light sources having different wavelengths.

Referring to FIG. 3, as illustrated in the upper drawing, a plurality of light sources 31 all indicate the same position for an alignment key 32 in an ideal situation in which there is no deformation in the alignment key 32. However, as illustrated in the lower drawing, deformation of the alignment key 34 may be caused by other processes such as etching or chemical mechanical polishing (CMP), causing the plurality of light sources 33 to indicate different positions. Accordingly, the alignment data A1 may include information on the deformation of the alignment key (hereinafter referred to as “incoming information”).

For example, FIG. 4 illustrates the alignment data A1 for each of the plurality of shots in a wafer 40 using vectors for each light source. As seen in the enlarged view of a shot 41, alignment data 4 indicates that positions of each light source differ due to deformation of an alignment key.

As illustrated in FIG. 4, the alignment data A1 only includes information on positions measured for each light source related to the corresponding shot, but does not include information on a relationship between shots. Due to characteristics of the semiconductor process in which a plurality of shots have a positional relationship within a single wafer, it may be more advantageous for misalignment data prediction to learn a neural network by taking a positional relationship between the shots into consideration.

According to example embodiments, a GNN may be used to predict misalignment data from the alignment data A1. The GNN uses graphical data, including a vertex V and an edge E, as input data. Therefore, according to example embodiments, the preprocessing module 300 may convert the alignment data A1 into input data A2 including a vertex V and an edge E. The vertex V may have an alignment data value associated with each light source for each of the plurality of shots. The edge may include information on a positional relationship between the plurality of shots.

For example, FIG. 5 illustrates the input data A2 corresponding to alignment data A1 of a plurality of shots in the wafer 50 using vectors for each light source. As seen in an enlarged portion of the plurality of shots included in the wafer 50, not only alignment data 4 for each light source represented by a vector but also a relationship 5 with adjacent shots is illustrated for each of the four shots 51, 52, 53, and 54.

As described above, when input data is provided in the form of a graph, edge (E) connectivity, and edge (E) weight may be set using prior knowledge such as an operating method of exposure equipment or a distance from a center of a wafer.

Returning to FIG. 2, the neural network model 200 may include a latent vector extraction module 210, an attention module 220, and a misalignment data output module 230.

The latent vector extraction module 210 may obtain a first latent vector L1 based on the input data A2. To this end, the latent vector extraction module 210 may include a first GNN GNN1. The first GNN GNN1 may receive the input data A2 output from the preprocessing module 300, and extract the first latent vector L1.

The input data A2 may be encoded into a lower dimension while passing through the first GNN GNN1. Accordingly, the first latent vector L1 may have fewer channels than the input data A2. For example, when the input data A2 includes 24 pieces of channel information corresponding to 24 light sources, the first latent vector L1 may include 3-channel information corresponding to 3 light sources.

The attention module 220 may obtain or generate a third latent vector L3 by reflecting the importance of the plurality of light sources and the plurality of shots in the first latent vector L1.

According to example embodiments, the attention module 220 may generate a second latent vector L2 by reflecting the importance of each of the plurality of light sources in the first latent vector L1, and generate a third latent vector L3 by reflecting the importance of each of the plurality of shots in the second latent vector L2. To this end, the attention module 220 may include a channel attention module and a spatial attention module.

Referring to FIG. 2, the attention module 220 may calculate a channel-wise attention score corresponding to each of the plurality of light sources from the first latent vector L1 using the channel attention module. Accordingly, the attention module 220 may generate the second latent vector L2 based on a multiplication operation of the calculated channel-wise attention score and the first latent vector L1.

In addition, the attention module 220 may calculate a shot-wise attention score corresponding to each of the plurality of shots from the second latent vector L2 using the spatial attention module. Accordingly, the attention module 220 may generate the third latent vector L3 based on a multiplication operation of the calculated shot-wise attention score and the second latent vector L2.

However, example embodiments are not limited thereto. For example, unlike what is illustrated in FIG. 2, the attention module 220 may generate a second latent vector L2 by reflecting the importance of each of the plurality of shots in the first latent vector L1 using the spatial attention module. Then, the attention module 220 may generate a third latent vector L3 by reflecting the importance of each of the plurality of light sources in the second latent vector L2 using the channel attention module.

The attention module 220 may provide the third latent vector L3 to the misalignment data output module 230. According to example embodiments, the attention module 220 may flatten the third latent vector L3 and provide the flattened second latent vector L4 to the misalignment data output module 230. The flattened second latent vector L4 may not include edge (E) information on a positional relationship between a plurality of shots.

In some embodiments, according to examples, the attention module 220 may provide the third latent vector L3, as it is, to the misalignment data output module 230 without flattening the third latent vector L3. The flattening operation on the third latent vector L3 may be performed in the misalignment data output module 230.

The misalignment data output module 230 may obtain or generate misalignment data for each of the plurality of shots from the third latent vector L3 using the first MLP neural network MLP1. The edge (E) information may be removed and a flattened second vector L4 may be required to use the first MLP neural network MLP1. The flattening operation on the third latent vector L3 may be performed in the attention module 220 as described above, or may be performed in the misalignment data output module 230.

According to example embodiments, the misalignment data may include x-axis misalignment data, including a misalignment component in an x-axis direction, and y-axis misalignment data including a misalignment component in a y-axis direction. In addition, the first MLP neural network MLP1 may include an x-axis MLP neural network MLP1_x and a y-axis MLP neural network MLP1_y.

Accordingly, the misalignment data output module 230 may input the flattened second latent vector L4 to the x-axis MLP neural network MLP1_x to generate x-axis misalignment data. Also, the misalignment data output module 230 may input the flattened second latent vector L4 to the y-axis first MLP neural network MLP_y to obtain y-axis misalignment data.

For example, FIG. 6 illustrates misalignment data of a plurality of shots in a wafer 60 using vectors. Referring to an enlarged view of a portion of the plurality of shots, misalignment data 6 of each of nine shots is illustrated using a vector having x-axis and y-axis components. The misalignment data 6 of each shot may indicate how much the shot is misaligned relative to a previously exposed layer.

The weights included in the neural network model 200 may be learned or updated based on the first loss function. According to example embodiments, the first loss function may be defined by a mean squared error (MSE) as illustrated in the following equation 1.

$$MSE = \frac{1}{N} {\sum }_{i = 1}^{N} {( {y}_{i} - {y}_{i}^{′} )}^{2} \qquad Equation 1$$

where N is a size of a batch, yᵢ is misalignment data corresponding to an i-th wafer among N wafers in the batch, and y′ᵢ is misalignment label data corresponding to the i-th wafer among the N wafers in the batch.

However, the first loss function is not limited thereto. According to example embodiments, other functions such as mean absolute error (MAE) or Huber Loss may be used as the first loss function.

According to example embodiments, the weights included in the first GNN GNN1 and the attention module 220 may be updated using a second loss function for contrastive learning. For example, the second loss function may be defined by a correlation loss as illustrated in the following equation 2.

$$correlation loss = \frac{1}{{n}^{2}} {\sum }_{i = 0}^{n} {\sum }_{j = 0}^{n} {α}_{i j} {β}_{i j} \vert {ϕ}_{i j} - {Ω}_{i j} \vert \qquad Equation 2$$

where n is a size of a batch, ai is equal to 1_{n×n}−I_{n×n}, βᵢⱼ is an indicator for applying a feature value, and ϕᵢⱼ is equal to

$$\frac{{z}_{i} \cdot {z}_{j}}{‖ {z}_{i} ‖ ‖ {z}_{j} ‖} ,$$

Ωᵢⱼ is equal to

$$\frac{W {K}_{i} \cdot {WK}_{j}}{‖ {WK}_{i} ‖ ‖ {WK}_{j} ‖} .$$

In addition, Zᵢ and Zⱼ are third latent vectors L3 corresponding to arbitrary two wafers in the batch, and WKᵢ and WKⱼ are misalignment shape indices corresponding to the arbitrary two wafers in the batch.

For example, αᵢⱼ may be an n×n square matrix having a value of 0 when i and j are the same and having a value of 1 when i and j are different from each other. In addition, βᵢⱼ may be an indicator matrix prepared to apply different values depending on characteristics of a target layer. In addition, ϕᵢⱼ may be a cosine similarity matrix of the third latent vectors L3 corresponding to the arbitrary two wafers in the batch. In addition, Ωᵢⱼ may be a cosine similarity matrix of misalignment shape indices corresponding to the arbitrary two wafers in the batch.

A misalignment shape index used in the calculation of Ωᵢⱼ may be obtained through polynomial regression for misalignment label data of the wafer. For example, the misalignment shape index may be obtained through a polynomial of degree 3, as illustrated in the following equation 3. However, example embodiments are not limited thereto. According to some embodiments, the misalignment shape index may also be obtained through a polynomial of degree less than 3 or greater than or equal to 4.

$$rawX = {k}_{1} + {k}_{3} X + {k}_{5} Y + {k}_{7} {X}^{2} + {k}_{9} XY + {k}_{11} {Y}^{2} + {k}_{13} {X}^{3} + {k}_{15} {X}^{2} Y + {k}_{17} {XY}^{2} + {k}_{19} {Y}^{3} + ε \qquad Equation 3$$

$$rawY = {k}_{2} + {k}_{4} Y + {k}_{6} X + {k}_{8} {Y}^{2} + {k}_{10} XY + {k}_{12} {X}^{2} + {k}_{14} {Y}^{3} + {k}_{16} {XY}^{2} + {k}_{18} {X}^{2} Y + {k}_{20} {X}^{3} + ε$$

where raw X is x-axis misalignment label data, raw Y is y-axis misalignment label data, X is x coordinate of a shot, Y is the y coordinate of the shot, and & is a remainder. The x coordinate and the y coordinate of the shot may be a position of the shot relative to the center of the wafer.

Fitting coefficients k₁ to K₂₀ obtained through the polynomial of degree 3 as in the above equation 3 may be misalignment shape indices of the wafer. When the polynomial of degree 3 is used as described above, 10 x-axis shape indices k₁, k₃, k₅, k₇, k₉, k₁₁, k₁₃, k₁₅, k₁₇, and k₁₉ and 10 y-axis shape indices k₂, k₄, k₆, k₈, k₁₀, k₁₂, k₁₄, k₁₆, k₁₈, and k₂₀ may be obtained.

The meaning of each of the 20 shape indices k₁ to K₂₀ obtained using the polynomial of degree 3 may be as illustrated in FIG. 7. For example, k₁ may indicate how much the shots in the wafer have moved in the x direction. In addition, k₂ may indicate how much the shots have moved in the y direction. In addition, k₃ may indicate how much the shots are spread in the x direction relative to the center of the wafer. In addition, k₄ may indicate how much the shots are spread in the y direction relative to the center of the wafer. In addition, k₅ may indicate how much the shots rotate in the x direction relative to the center of the wafer. In addition, k₆ may indicate how much the shots rotate in the y direction relative to the center of the wafer. The meanings of the remaining K₇ to K₂₀ may be understood from the illustration provided. FIG. 8 is a diagram illustrating an example of a misalignment shape 72 of a corresponding wafer based on an example value 71 of a misalignment shape index.

The weights included in the first GNN GNN1 and the attention module 220 may be updated using the second loss function, as described above, to reflect a relationship between misalignment shape indices of wafers in a latent vector space. Accordingly, commonalities between wafers having similar misalignment shape indices and differences between wafers having different misalignment shape indices may be clearly learned in the neural network model 200.

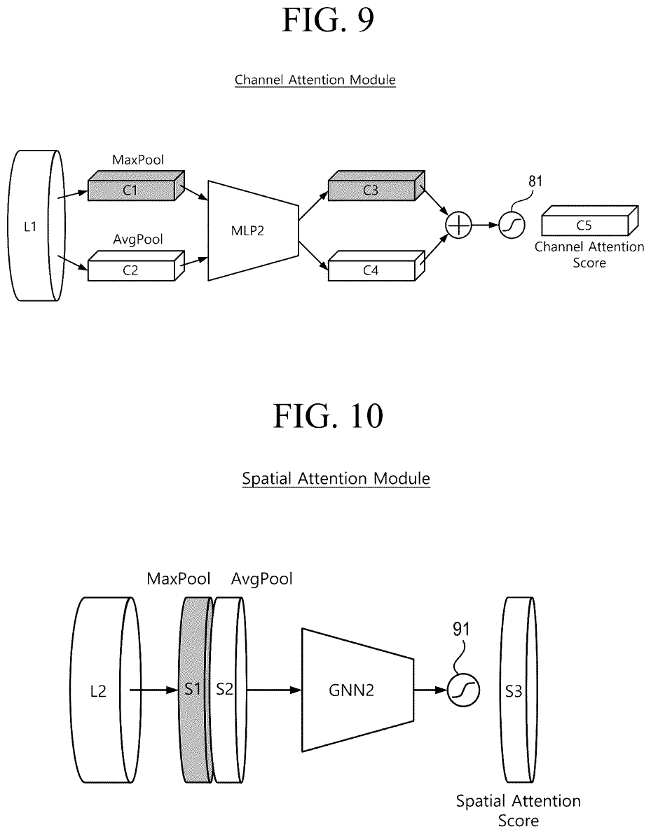

FIG. 9 is a diagram illustrating an example of a configuration of a channel attention module of FIG. 2. Referring to FIG. 9, the channel attention module may obtain a first vector C1 including a maximum value for each channel through a maximum pooling operation on the first latent vector L1, and obtain a second vector C2 including an average value for each channel through an average pooling operation on the first latent vector L1.

The first vector C1 and the second vector C2 do not include information between shots. Therefore, the channel attention module may obtain a channel-wise attention score using the second MLP neural network MLP2.

For example, the channel attention module may input the first vector C1 and the second vector C2 to the second MLP neural network MLP2 to obtain a third vector C3 corresponding to the first vector C1 and a fourth vector C4 corresponding to the second vector C2. Accordingly, the channel attention module may obtain channel-wise attention scores C5 from the sum of the third vector C3 and the fourth vector C4 using a sigmoid activation function 81.

As a result, the attention module 220 may generate the second latent vector L2 based on a multiplication operation of the calculated channel-wise attention score C5 and the first latent vector L1, as illustrated in FIG. 2.

According to example embodiments, a correlation between a wafer region and misalignment may be analyzed using the channel-wise attention score calculated as described above.

FIG. 10 is a diagram illustrating an example of a configuration of a spatial attention module of FIG. 2. Referring to FIG. 10, a spatial attention module may obtain a fifth vector S1 including a maximum value for each shot through a maximum pooling operation on the second latent vector L2, and obtain a sixth vector S2 including an average value for each shot through an average pooling operation on the second latent vector L2.

The fifth vector S1 and the sixth vector S2 may include information between shots. Therefore, the spatial attention module may obtain a shot-wise attention score using the second GNN GNN2.

For example, the spatial attention module may input the concatenated fifth vector S1 and sixth vector S2 to the second GNN GNN2 to obtain a shot-wise attention score S3 from an output of the second GNN GNN2 using a sigmoid activation function 91.

As a result, the attention module 220 may generate the third latent vector L3 based on a multiplication operation of the calculated shot-wise attention score S3 and the second latent vector L2.

According to example embodiments, a correlation between a light source and misalignment may be analyzed using the shot-wise attention score calculated as described above.

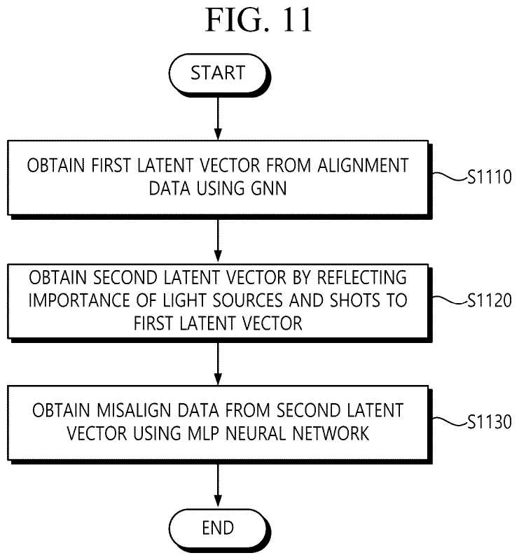

FIG. 11 is a flowchart illustrating a method of obtaining misalignment data according to example embodiments. The method of obtaining misalignment data illustrated in FIG. 11 may be performed by the computing device 100 of FIG. 1, but example embodiments are not limited thereto.

Referring to FIG. 11, in operation S1110, the computing device 100 may obtain a first latent vector L1 from alignment data of a plurality of shots in a wafer measured based on a plurality of light sources having different wavelengths using the first GNN GNN1.

The alignment data may correspond to a single target layer to be stacked on the wafer, and may be data measured for each of the plurality of light sources based on alignment keys, respectively corresponding to the plurality of shots, before an exposure operation on the target layer. The misalignment data may include information on how much each of the plurality of shots is misaligned relative to a layer previously exposed to the target layer.

For example, the computing device 100 may convert the alignment data into graphical input data and input the input data to the first GNN GNN1 to obtain the first latent vector L1.

In operation S1120, the computing device 100 may obtain the third latent vector L3 by reflecting the importance of the plurality of light sources and the plurality of shots in the first latent vector L1.

According to example embodiments, the computing device 100 may obtain a second latent vector L2 by reflecting the importance of each of the plurality of light sources in the first latent vector L1, and obtain a third latent vector L3 by reflecting the importance of each of the plurality of shots in the second latent vector L2.

For example, the computing device 100 may calculate a channel-wise attention score C5 corresponding to each of the plurality of light sources from the first latent vector L1 using the channel attention module, and obtain the second latent vector L2 based on a multiplication operation of the channel-wise attention score C5 and the first latent vector L1. In addition, the computing device 100 may calculate a shot-wise attention score S3 corresponding to each of the plurality of shots from the second latent vector L2 using the spatial attention module, and obtain the third latent vector L3 based on a multiplication operation of the shot-wise attention score S3 and the second latent vector L2.

In operation S1130, the computing device 100 may obtain misalignment data for each of the plurality of shots from the third latent vector L3 using the first MLP neural network MLP1.

According to example embodiments, the computing device 100 may flatten the third latent vector L3. Also, the computing device 100 may input the flattened second latent vector L4 to the x-axis MLP neural network MLP1_x to obtain x-axis misalignment data. Also, the computing device 100 may input the flattened second latent vector L4 to the y-axis MLP neural network MLP1_y to obtain y-axis misalignment data.

The computing device 100 may learn the neural network model 200 using the first loss function. The first loss function may be defined by a mean squared error (MSE) as illustrated in Equation 1. The computing device 100 may calculate a value of the first loss function and update weights included in the first GNN GNN1, the second GNN GNN2, the second MLP neural network MLP2, and the first MLP neural networks MLP1_x, MLP1_y through a backpropagation algorithm based on the calculated value of the first loss function. Accordingly, an error between the misalignment data and the misalignment label data may be reduced.

In addition, the computing device 100 may learn the first GNN GNN1 and the attention module 220 using the second loss function. The second loss function may be defined by the correlation loss equation as illustrated in Equation 2. The computing device 100 may calculate a value of the second loss function and update weights included in the first GNN GNN1, the second GNN GNN2, and the second MLP neural network MLP2 based on the calculated value of the second loss function. Accordingly, the similarity of the misalignment shape indices of the wafers may be reflected in the latent vector space.

The misalignment data indicates how much each of the plurality of shots is misaligned relative to a previously exposed layer, so that an equipment control value of the exposure equipment may be adjusted based on the misalignment data. Therefore, the misalignment data may correspond to the equipment control value, and the misalignment shape index may correspond to the shape index of the equipment control value. As a result, in the above-described various embodiments, the contents related to the misalignment data may be equivalently understood as the contents related to the equipment control value.

According to the above-described various embodiments, misalignment data may be obtained using alignment data, which may contribute to improving the yield of a semiconductor process. For example, misalignment data may be obtained through a neural network model based on alignment data, so that misalignment data for a target layer may be obtained before an exposure operation on the target layer. In addition, the alignment data is whole number data measured before exposure on all wafers, so that misalignment data for all of the wafers may be obtained. In addition, a variation trend of the misalignment shape index or the shape index of the equipment control value may be automatically tracked. Thus, at least a portion of the exposure process may be automatically controlled, or engineers may be alerted when it is time to update the equipment control value. Therefore, the use of the misalignment data may contribute to improving the yield of semiconductor processes.

The various embodiments may be implemented as software including instructions stored in a machine-readable storage medium. The machine is a device that is able to fetch a stored instruction from the storage medium and operate based on the fetched instruction, and may include the computing device 100 according to example embodiments.

When the instruction is executed by a processor, the processor may perform the function corresponding to the instruction directly or using other components under the control of the processor. The instructions may include a code generated by a compiler or a code executable by an interpreter. The machine-readable storage medium may be provided in the form of a non-transitory storage medium. The term “non-transitory” means that a storage medium does not include a signal and is tangible, but does not distinguish whether data is stored semi-permanently or temporarily in the storage medium.

The method according to various embodiments may be provided in a computer program product. The computer program product may be traded as a product between a seller and a buyer. The computer program product may be distributed in the form of a machine-readable storage medium, or may be distributed online via an application store. If the computer program product is distributed online, at least a portion of the computer program product may be temporarily generated or at least temporarily stored in the machine-readable storage medium, such as memory of the manufacturer's server, a server of the application store, or a relay server.

As set forth above, according to example embodiments, misalignment data may be obtained using alignment data.

While example embodiments have been shown and described above, it will be apparent to those skilled in the art that modifications and variations could be made without departing from the scope of the present inventive concept as defined by the appended claims.

What is claimed is:

1. A method for obtaining misalignment data of an exposure equipment, performed by a computing device comprising at least one processor, the method comprising:
obtaining a first latent vector from alignment data of a plurality of shots within a wafer measured based on a plurality of light sources having different wavelengths, using a first graph neural network (GNN);
obtaining a third latent vector by reflecting an importance of the plurality of light sources and the plurality of shots in the first latent vector;
obtaining misalignment data for each of the plurality of shots from the third latent vector using a first multilayer perceptron (MLP) neural network; and
adjusting an equipment control value of the exposure equipment based on the misalignment data for each of the plurality of shots in the wafer.

2. The method of claim 1, wherein the alignment data corresponds to a single target layer among a plurality of layers stacked on the wafer, and comprises data measured for each of the plurality of light sources based on alignment keys, respectively corresponding to the plurality of shots, before an exposure operation on the single target layer, and
wherein the misalignment data comprises misalignment information of each of the plurality of shots relative to a layer exposed prior to the single target layer.

3. The method of claim 1, wherein the obtaining the first latent vector comprises:
converting the alignment data into graphical input data; and
inputting the graphical input data to the first GNN to obtain the first latent vector.

4. The method of claim 1, wherein obtaining the third latent vector by reflecting the importance comprises:
obtaining a second latent vector by reflecting an importance of each of the plurality of light sources in the first latent vector; and
obtaining the third latent vector by reflecting an importance of each of the plurality of shots in the second latent vector.

5. The method of claim 4, wherein the obtaining the second latent vector comprises:
calculating a channel-wise attention score corresponding to each of the plurality of light sources from the first latent vector using a channel attention module; and
obtaining the second latent vector based on a multiplication of the channel-wise attention score and the first latent vector.

6. The method of claim 5, wherein the channel attention module comprises a second MLP neural network, and
wherein the calculating the channel-wise attention score comprises:
obtaining a first vector comprising a channel-wise maximum value through a maximum pooling operation on the first latent vector and obtaining a second vector comprising a channel-wise average value through an average pooling operation on the first latent vector;
inputting the first vector and the second vector to the second MLP neural network to obtain a third vector corresponding to the first vector and a fourth vector corresponding to the second vector; and
obtaining the channel-wise attention score from a sum of the third vector and the fourth vector using a sigmoid activation function.

7. The method of claim 4, wherein the obtaining the third latent vector comprises:
calculating a shot-wise attention score corresponding to each of the plurality of shots from the second latent vector using a spatial attention module; and
obtaining the third latent vector based on a multiplication of the shot-wise attention score and the second latent vector.

8. The method of claim 7, wherein the spatial attention module comprises a second GNN, and
wherein the calculating the shot-wise attention score comprises:
obtaining a fifth vector comprising a shot-wise maximum value through a maximum pooling operation on the second latent vector and obtaining a sixth vector comprising a shot-wise average value through an average pooling operation on the second latent vector;
inputting the concatenated fifth and sixth vectors to the second GNN; and
obtaining the shot-wise attention score from an output of the second GNN using a sigmoid activation function.

9. The method of claim 1, wherein the misalignment data comprises x-axis misalignment data comprising a misalignment component in an x-axis direction and y-axis misalignment data comprising a misalignment component in a y-axis direction, and
wherein the first MLP neural network comprises an x-axis MLP neural network and a y-axis MLP neural network.

10. The method of claim 9, wherein the obtaining the misalignment data comprises:
flattening the third latent vector to obtain a flattened third latent vector;
inputting the flattened third latent vector to the x-axis MLP neural network to obtain the x-axis misalignment data; and
inputting the flattened third latent vector to the y-axis MLP neural network to obtain the y-axis misalignment data.

11. The method of claim 1, comprising:
updating weights included in the first GNN and the first MLP neural network using a first loss function to reduce an error between the misalignment data and misalignment label data corresponding to the alignment data.

12. The method of claim 11, wherein the first loss function is defined by a mean squared error (MSE) comprising
$$MSE = \frac{1}{N} {\sum }_{i = 1}^{N} {( {y}_{i} - {y}_{i}^{′} )}^{2}$$
wherein N is a size of a batch, yᵢ is misalignment data corresponding to an i-th wafer among N wafers in the batch, and y′ᵢ is misalignment label data corresponding to the i-th wafer among the N wafers in the batch.

13. The method of claim 1, comprising:
updating weights included in the first GNN using a second loss function for contrastive learning to reflect a similarity between misalignment shape indices of wafers in a batch in the third latent vector,
wherein respective misalignment shape indices of each of the wafers comprises coefficients obtained through polynomial regression from misalignment label data corresponding to each of the wafers.

14. The method of claim 13, wherein the second loss function is defined by correlation loss comprising
$$correlation loss = \frac{1}{{n}^{2}} {\sum }_{i = 0}^{n} {\sum }_{j = 0}^{n} {α}_{i j} {β}_{i j} \vert {ϕ}_{i j} - {Ω}_{i j} \vert$$
wherein n is a size of a batch, αᵢⱼ is an n×n square matrix having a value of 0 when i and j are same and having a value of 1 when i and j are different from each other, βᵢⱼ is an indicator matrix prepared to apply different values depending on characteristics of a target layer, ϕᵢⱼ is a cosine similarity matrix of third latent vectors including the third latent vector corresponding to arbitrary two wafers of the wafers in the batch, and Ωᵢⱼ is a cosine similarity matrix of misalignment shape indices corresponding to the arbitrary two wafers of the wafers in the batch.

15. A method for obtaining misalignment data of an exposure equipment for a wafer using a neural network model, the method comprising:
converting alignment data of a plurality of shots measured for each of a plurality of light sources into input data comprising a positional relationship between the plurality of shots;
inputting the input data to a graph neural network (GNN) to obtain a first latent vector;
obtaining a third latent vector by reflecting an importance of each light source and an importance of each shot in the first latent vector;
predicting misalignment data for each of the plurality of shots from the third latent vector using a multilayer perceptron (MLP) neural network; and
adjusting an equipment control value of the exposure equipment based on the misalignment data for each of the plurality of shots in the wafer.

16. The method of claim 15, wherein the obtaining the third latent vector comprises:
calculating a channel-wise attention score corresponding to each of the plurality of light sources from the first latent vector using a channel attention module, and obtaining a second latent vector based on a multiplication a product of the channel-wise attention scores and the first latent vector; and
calculating a shot-wise attention score corresponding to each of the plurality of shots from the second latent vector using a spatial attention module, and obtaining the third latent vector based on a multiplication of the shot-wise attention score and the second latent vector.

17. The method of claim 16, comprising:
updating weights included in the GNN, the channel attention module, the spatial attention module, and the MLP neural network using a first loss function to reduce an error between the misalignment data and misalignment label data corresponding to the alignment data.

18. The method of claim 16, comprising:
updating weights included in the GNN, the channel attention module, and the spatial attention module using a second loss function for contrastive learning to reflect a relationship between misalignment shape indices of wafers in a batch in the third latent vector,
wherein respective misalignment shape indices of each of the wafers comprises coefficients obtained through polynomial regression from misalignment label data corresponding to each of the wafers.

19. The method of claim 18, wherein the second loss function is defined by correlation loss comprising
$$correlation loss = \frac{1}{{n}^{2}} {\sum }_{i = 0}^{n} {\sum }_{j = 0}^{n} {α}_{i j} {β}_{i j} \vert {ϕ}_{i j} - {Ω}_{i j} \vert$$
wherein n is a size of a batch, αᵢⱼ is an n×n square matrix having a value of 0 when i and j are same and having a value of 1 when i and j are different from each other, βᵢⱼ is an indicator matrix prepared to apply different values depending on characteristics of a target layer, ϕᵢⱼ is a cosine similarity matrix of third latent vectors including the third latent vector corresponding to arbitrary two wafers of the wafers in the batch, and Ωᵢⱼ is a cosine similarity matrix of misalignment shape indices corresponding to the arbitrary two wafers of the wafers in the batch.

20. A method for obtaining misalignment data for an exposure equipment, the method comprising:
converting alignment data of a plurality of shots within a wafer, measured using a plurality of light sources having different wavelengths, into a graphical input data;
inputting the graphical input data to a graph neural network (GNN) to obtain a first latent vector;
obtaining a third latent vector by reflecting an importance of the plurality of light sources and the plurality of shots in the first latent vector;
flattening the third latent vector;
inputting the flattened third latent vector to an x-axis MLP neural network to predict x-axis misalignment data comprising an x-axis misalignment component;
inputting the flattened third latent vector to a y-axis MLP neural network to predict y-axis misalignment data comprising a y-axis misalignment component; and
adjusting an equipment control value of the exposure equipment based on the y-axis misalignment data and the x-axis misalignment data for each of the plurality of shots in the wafer.
